(19) United States
(12) Patent Application Publication
(10) Pub. No.: US 2023/0006068 A1
(43) Pub. Date: Jan. 5, 2023

(54) VERTICAL TRANSISTOR STRUCTURES AND METHODS UTILIZING DEPOSITED MATERIALS

(71) Applicant: Tokyo Electron Limited, Tokyo (JP)

(72) Inventors: H. Jim Fulford, Albany, NY (US); Mark I. Gardner, Albany, NY (US); Partha Mukhopadhyay, Albany, NY (US)

(73) Assignee: Tokyo Electron Limited, Tokyo (JP)

(21) Appl. No.: 17/529,211

(22) Filed: Nov. 17, 2021

Related U.S. Application Data
(60) Provisional application No. 63/217,359, filed on Jul. 1, 2021.

(51) Int. Cl. H01L 29/786; H01L 29/66; H01L 27/092

(52) U.S. Cl. CPC H01L 29/78642; H01L 29/7869; H01L 29/66969; H01L 27/092

(57) ABSTRACT

Vertical transistors and methods of manufacturing vertical transistors are disclosed. The method can include forming a stack of layers. The stack of layers includes a first sub-stack for a first transistor structure. The first sub-stack includes at least three layers of a conductive material separated by one or more layers of a dielectric material. The stack of layers includes a second sub-stack for a second transistor structure. The second sub-stack includes at least three layers of a conductive material separated by one or more layers of a dielectric material. The first and second sub-stacks are separated by dielectric materials. The method includes forming a channel opening in the stack, and providing a first channel structure that includes a semiconductive oxide material aligned with the first transistor structure. The method includes selectively forming a capping layer on the first channel structure, and providing a second channel structure within the channel opening.

### CROSS-REFERENCE TO RELATED APPLICATIONS

This application claims priority to U.S. Provisional Patent Application Ser. No. 63/217,359, filed Jul. 1, 2021, which is incorporated by reference in its entirety.

### TECHNICAL FIELD

The present invention relates generally to the field of manufacturing semiconductor devices.

### BACKGROUND

In the manufacture of a semiconductor devices (especially on the microscopic scale), various fabrication processes are executed, such as film-forming depositions, etch mask creation, patterning, material etching and removal, and doping treatments. These processes are performed repeatedly to form desired semiconductor device elements on a substrate. Conventional micro microfabrication techniques only manufacture transistors in one plane, while wiring or metallization is formed above the active device plane. Such devices are accordingly characterized as two-dimensional (2D) circuits, manufactured using 2D fabrication techniques. Although scaling efforts have greatly increased the number of transistors per unit area in 2D circuits, these 2D fabrication techniques are approaching physical atomic limitations with single digit nanometer semiconductor device fabrication nodes. Semiconductor device fabricators have expressed a desire for different manufacturing techniques and configurations of devices to increase density of semiconductor circuitry.

### SUMMARY

Three-dimensional (3D) integration, e.g., a stacking (or vertical arrangement) of multiple semiconductor devices (e.g., transistor structures), aims to overcome scaling limitations experienced in planar devices by increasing transistor density in volume rather than area. Although device stacking has been successfully demonstrated and implemented by the flash memory industry with the adoption of 3D NAND, applying similar techniques to random logic designs is substantially more difficult. 3D integration for logic chips, including central processing units (CPU), graphics processing units (GPU), and field-programmable gate arrays (FPGA) are being pursued.

At least one aspect of the present disclosure is directed to a method. The method can include forming a stack of layers. The stack of layers can include a first sub-stack for a first transistor structure. The first sub-stack can include at least three layers of at least one conductive material separated by one or more layers of at least one dielectric material. The stack of layers can include a second sub-stack for a second transistor structure. The second sub-stack can include at least three layers of at least one conductive material separated by one or more layers of at least one dielectric material. The first and second sub-stacks can be separated by one or more dielectric materials. The method can include forming a channel opening in the stack of layers. The method can include providing a first channel structure within the channel opening. The first channel structure can include any deposited layer, such as a semiconductive oxide material and aligned with the first transistor structure. The method can include selectively forming a capping layer on the first channel structure. The method can include providing a second channel structure within the channel opening. The second channel structure can include any deposited layer, such as a semiconductive oxide material and aligned with the second transistor structure.

The method can include removing a core region of the first and second channel structures and replacing the core region with a core dielectric. In some implementations, the method can include removing the capping layer and replacing the capping layer with the core dielectric when replacing the core region with the core dielectric. In some implementations, the capping layer is a seed layer and the second channel structure is provided by selective formation utilizing the seed layer. In some implementations, the first channel structure and the second channel structure are the same material. In some implementations, the first channel structure and the second channel structure are a different material.

At least one other aspect of the present disclosure is directed to a vertical field effect transistor (VFET) structure. The VFET structure can include a stack of layers. The stack of layers can include a first sub-stack for a first transistor structure. The first sub-stack can include at least three layers of at least one conductive material separated by one or more layers of at least one dielectric material. The stack of layers can include a second sub-stack for a first transistor structure. The second sub-stack including at least three layers of at least one conductive material separated by one or more layers of at least one dielectric material. The first and second sub-stacks are separated by one or more dielectric materials. The VFET structure can include a channel opening in the stack of layers. The VFET structure can include a first channel structure within the channel opening. The first channel structure can include a semiconductive oxide material and aligned with the first sub-stack. The VFET structure can include a second channel structure within the channel opening. The second channel structure can include a semiconductive oxide material and aligned with the second sub-stack. The VFET structure can include an insulating layer interposed between the first and second channel structures.

The VFET structure can include a core region including a core dielectric material that extends through one or more of the first and second channel structures. In some implementations, the VFET structure can include a capping layer positioned on the second channel structure that insulates the second channel structure from an external environment. In some implementations, the insulating layer interposed between the first and second channel structures includes the core dielectric material. In some implementations, the insulating layer interposed between the first and second channel structures includes a different material than the core dielectric material. In some implementations, the first channel structure and the second channel structure comprise the same material. In some implementations, the first channel structure and the second channel structure comprise a different material.

At least one other aspect of the present disclosure is directed to a complementary vertical field effect transistor (CFET) structure. The CFET structure can include a stack of layers. The stack of layers can include a first sub-stack for a first transistor structure. The first sub-stack can include at least three layers of at least one conductive material separated by one or more layers of at least one dielectric material. The stack of layers can include a second sub-stack for a first transistor structure. The second sub-stack can include at least three layers of at least one conductive material separated by one or more layers of at least one dielectric material. The first and second sub-stacks can be separated by one or more dielectric materials. The CFET structure can include a channel opening in the stack of layers. The CFET structure can include a first channel structure within the channel opening, the first channel structure comprising a semiconductive oxide material providing a P- or N- channel type for the first transistor structure. The CFET structure can include a second channel structure within the channel opening, the second channel structure comprising a semiconductive oxide material providing a P- or N- channel type for the second transistor structure, the channel type being different than the first channel structure. The CFET structure can include an insulating layer interposed between the first and second channel structures.

The CFET structure can include a core region including a core dielectric material that extends through each of the first and second channel structures. In some implementations, the CFET structure can include a capping layer positioned on the second channel structure that insulates the second channel structure from an external environment. In some implementations, the insulating layer interposed between the first and second channel structures can include the core dielectric material. In some implementations, the insulating layer interposed between the first and second channel structures can include a different material than the core dielectric material. In some implementations, the first channel structure and the second channel structure can include the same material. In some implementations, the first channel structure and the second channel structure can include a different material.

At least one other aspect of the present disclosure is directed to a VFET structure. The VFET structure can include a stack of layers including a sub-stack for a transistor structure. The sub-stack can include at least three layers of at least one conductive material separated by one or more layers of at least one dielectric material. The VFET structure can include a channel opening in the stack of layers. The VFET structure can include a channel structure within the channel opening. The channel structure can include a semiconductive oxide material and can be aligned with the sub-stack. The VFET structure can include a core region including a core dielectric material that extends through the channel structure.

These and other aspects and implementations are discussed in detail below. The foregoing information and the following detailed description include illustrative examples of various aspects and implementations and provide an overview or framework for understanding the nature and character of the claimed aspects and implementations. The drawings provide illustration and a further understanding of the various aspects and implementations and are incorporated in and constitute a part of this specification. Aspects can be combined and it will be readily appreciated that features described in the context of one aspect of the invention can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1-10 show top and cross-sectional views of a first process flow to form 3D vertical semiconductor devices, according to an embodiment; and

FIGS. 11-13 show top and cross-sectional views of a second process flow for forming 3D vertical semiconductor devices, according to an embodiment; and

FIG. 14 shows a flow diagram of an example method for fabricating transistor structures using the process flows described in connection with FIGS. 1-13, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

This application relates to vertically oriented transistor devices and their methods of manufacture. More specifically, described herein are structures in which the current between the drain and source is primarily in the direction normal to the surface of the die, e.g., vertical field-effect transistor (VFET) and Complementary Field Effect Transistor (CFET) structures.

Logic devices are conventionally formed in horizontal planar configurations. However, limitations on the amount of area and required density of devices in a given footprint increasingly necessitate the use of novel structures. The present application provides devices oriented in a vertical, or 3D, direction. Devices are oriented such that current flows in the vertical or z-direction allowing arrays of transistors to be stacked relative to the primary planar surface of the array or underlying substrate.

According to the techniques described, 3D VFET devices may be created on any suitable substrate including conductive, semiconductive, or dielectric substrates. The underlying substrate may be a passive structure such as a handle wafer or passive interposer, or may have active devices, such as memory devices, circuitry, etc. Advantageously, VFETs may be provided above other active devices allowing for close proximity between devices. The VFETs may also be stacked as all one conductivity type, e.g., N-type or P-type or the conductivity type may be combined, such one or more N-type devices over or under one or more P-type devices in the stack. Such configurations may include, but are not limited to so-called CFETs, i.e., complementary Field Effect Transistors. CFET structures which here include a gate-all-around (GAA) structure.

According to certain implementations, one or more transistor structures are formed by stacking layers to form a source (or drain), gate, and drain (or source) separated by one or more dielectric layers to isolate each portion of the transistor. The channel is oriented in a z-direction, e.g., perpendicular to the direction that the layers are stacked. A high-k dielectric material is provided between the gate and the channel as will be described more fully below.

The techniques provided herein can utilize conductive dielectric materials (sometimes referred to herein as “conductive channels”), which may have similar properties to semiconductor materials, to fabricate vertical 3D transistors. For example, certain materials, when combined with oxygen, may form new materials that exhibit semiconductor properties (e.g., it can turn “off” with low off-state leakage current, or can become highly conductive under certain circumstances, etc.). Some examples of N-type conductive channels include In₂O₃, SnO₂, InGaZnO, and ZnO. One example of a P-type conductive channel is SnO. Additionally or alternatively, the channel may comprise a 2D material. Some example 2D materials for use in forming the channel include, but are not limited to, WS₂, WSe₂, WTe₂, MoS₂, MoSe₂, MoTe₂, HfS₂, ZrS₂, and TiS₂, GaSe, InSe, phosphorene, and other similar materials. These materials may be deposited by an atomic layer deposition (ALD) process and may be, for example, 5-15 angstroms thick, the thinness lending to their name—2D material. The materials may be annealed during or after the device formation process to recrystallize or grow the crystals and thereby improve electrical characteristics. For the sake of simplicity, the use of conductive dielectrics will be disclosed.

Further, various techniques may be implemented to form the high-k barrier between the conductive channels and the gate electrode. One such technique utilizes a selective deposition of a high-k dielectric to form the transistor gates. In some implementations, a gate-recessing technique is utilized to allow a more uniform layer of doped conductive oxide material to form along the sidewall of the opening. Another, similar technique provides a non-selective deposition of the high-k dielectric in the gate-recessed opening, in conjunction with self-aligned directional etching. These techniques may also be implemented to fabricate stacked transistors of the same type by utilizing the same conductive oxide for two or more transistor layers. These and other aspects are described in further detail herein.

Reference will now be made to the Figures, which for the convenience of visualizing the 3D fabrication techniques described herein, illustrate a substrate undergoing a process flow in both top and cross-sectional views. Unless expressly indicated otherwise, each Figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, although most of the figures show various layers defining transistor structures or other electric structures in a circular configuration, other shapes are also contemplated, and indeed the techniques described herein may be implemented in any shape or geometry. In addition, examples in which two transistors or devices are shown stacked on top of one another are shown for illustrative purposes only, and for the purposes of simplicity. Indeed, the techniques described herein may provide for one to any number N stacked devices. Although the devices fabricated using these techniques are shown as transistors, it should be understood that any type of electric or electronic device may be manufactured using such techniques, including but not limited to transistors, variable resistors, resistors, and capacitors.

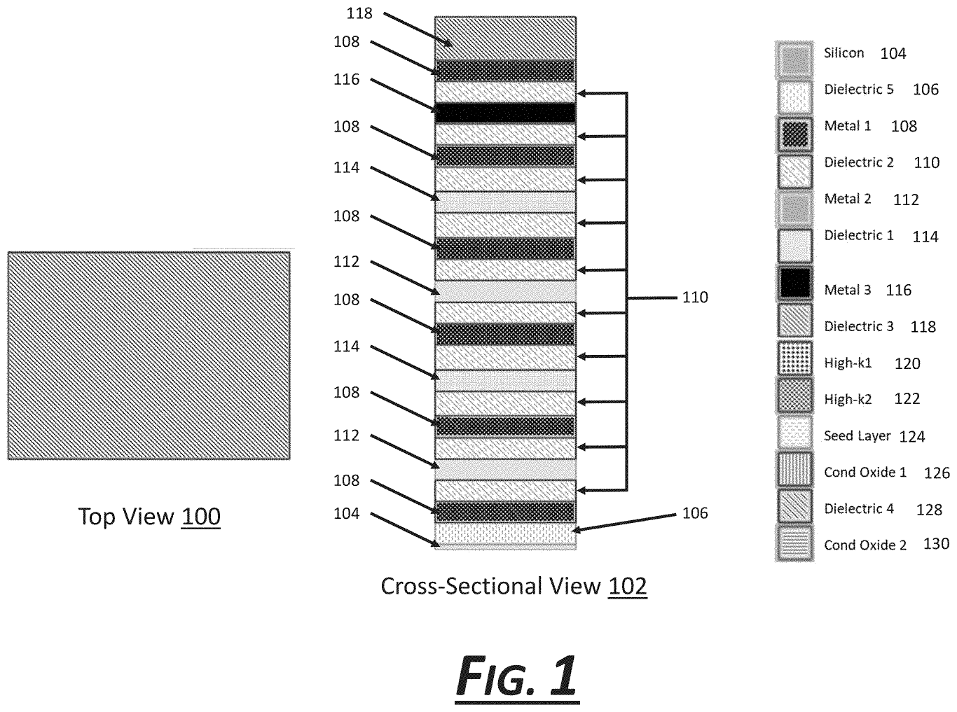

FIGS. 1-10 show a process flow for the manufacture of 3D VFET or CFET transistor stacks, or other types of electric or electronic devices. Each of the FIGS. 1-10 generally refer to one or more process steps in a process flow, each of which are described in detail in connection with the respective Figure. For the purposes of simplicity and ease of visualization, some reference numbers may be omitted from some Figures. As used herein, the terms “first,” “second,” “third,” and “fourth” with respect to particular layers of the stack shown in FIGS. 1-10 refer to the order of the layers relative to the substrate 104. For example, a “first” layer of a particular type refers to the specified type of layer which is closest to the substrate 104. Likewise, a “second” layer of a particular type refers to the specified type of layer which is second closest to the substrate 104, and so on. Referring to FIG. 1, illustrated is a top view 100 and a cross-sectional view 102 of a device. A substrate 104 (e.g., Si, shown as “Silicon” in the legend) is provided which may be active or passive and may comprise dielectric, conductive or semiconductive materials or any combination thereof. One or more first dielectric layers 106 (e.g., shown as “Dielectric 5” in the legend) may be provided on the substrate 104 to isolate the VFET structure from the underlying substrate. The dielectric materials described herein may be any type of dielectric material that is capable of being disposed, patterned, or otherwise provided on the various layers described herein. Some examples of dielectric materials can include, but are not limited to, oxide materials.

The substrate 104 may remain in the final structure or may be removed during or after the formation of the VFET structure. The term source/drain (S/D) will be used to describe layers that may be used as either a source or a drain of a transistor structure. The first S/D layer 108 (e.g., shown as “Metal 1” in the legend) may be formed directly on the substrate 104 or on the one or more dielectric layers 106 described above. The S/D layers 108 may be any type of conductive metal suitable to form a source or drain electrode in a semiconductor device, including copper, gold, silver, platinum, nickel, tungsten, ruthenium, or other types of conductive metals or alloys. An insulating dielectric 110 (e.g., shown as “Dielectric 2” in the legend) is formed on the first S/D layer 108.

A gate layer 112 (e.g., shown as “Metal 2” in the legend) may then be formed on top of the first insulating dielectric layer 110. A second insulating dielectric layer 110, and then a second S/D layer 108, may be formed on the gate layer 112. The gate layer 112 may be a different material than the first and second S/D layers 108. A third insulating dielectric layer 110 may then be deposited on top of the second S/D layer 108 to complete a first transistor structure. In a multi-transistor stack these layers would constitute a first sub-stack. As shown in the cross-sectional view 102, a transistor structure can include four dielectric layers (with the first transistor having one dielectric layer be the dielectric layer 106, which separates the first transistor structure from the substrate 104) and three conductive metal layers (the two S/D layers 108 and one gate layer 112).

Subsequent transistor structures (e.g., second sub-stacks, third sub-stacks, etc.) may be stacked above the first transistor structure, by depositing similar layers. One or more insulating dielectric layers 114 may be deposited between adjacent transistor structures. These layers in the stack of layers may be formed without a mask, such that each layer forms a blanket layer over the prior layer. The gate layers 112 or 116 may be a different material than the S/D layers 108 to allow selectivity in etch and deposition processes. Moreover, the gate layer for a P-type device may be selected to be different from the gate layer of an N-type device. A non-exhaustive list of potential materials to use for the gate layer includes ruthenium (Ru), tantalum nitride (TaN), titanium nitride (TiN), and tungsten (W), tungsten nitride (VVN), titanium carbide (TiC), gallium (Ga), gadolinium (Gd), titanium oxynitride (TiON), tantalum silicon nitride (TaSiN), titanium silicon nitride (TiSiN), molybdenum (Mo), aluminum (Al), copper (Cu) and combinations/stacks/alloys of these or similar materials.

Once the layers are formed, each VFET structure or vertical group of VFET structures may be patterned as is well understood in the art to separate adjacent transistor structures in the x-y direction (e.g., where the x-y plane is perpendicular to the z-direction). As this pattern process is well described and documented elsewhere, it will not be expounded upon here in the interest of brevity and focus. Additionally, electrical connections between transistor structures may be formed by patterning the conductive layers described herein, as well as by forming vias to electrically connect different layers. As such, transistor stacks that are isolated in the x-y plane may be electrically connected with one another to form logical or electronic circuits.

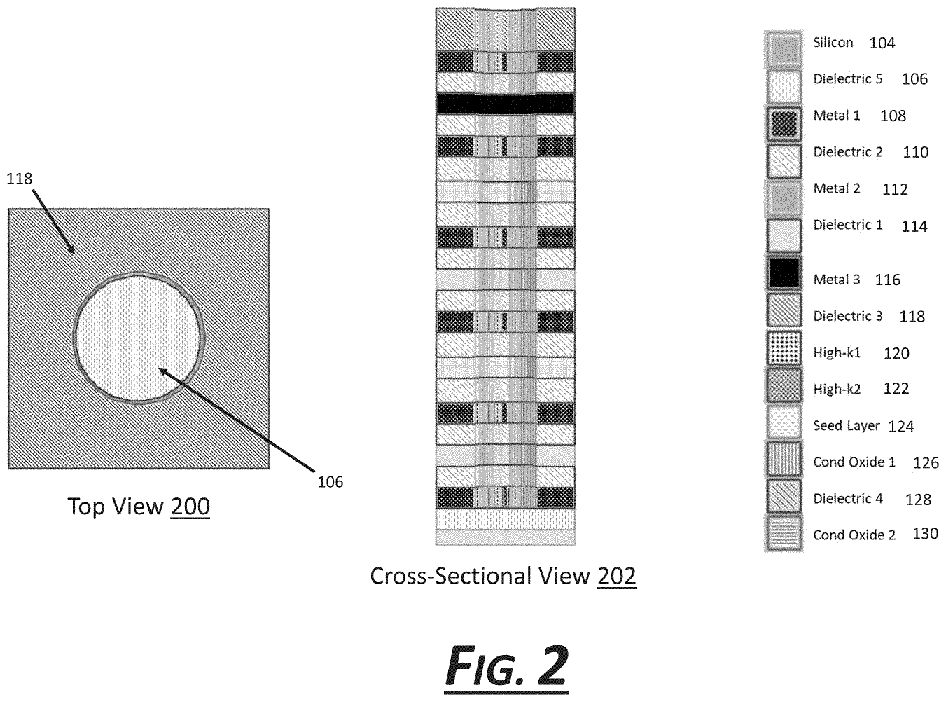

Once the stack of layers has been formed to include one or more sub-stacks, the process flow proceeds to the next stage shown in FIG. 2. FIG. 2 illustrates a top view 200 and a cross-sectional view 202 of a device at the next stage in the process flow. Either before or after patterning the structures into individual transistors or stacks of transistors, one or more channels (sometimes referred to as a “transistor body openings” or “channel openings”) may be formed. To form the channel openings, a mask (e.g., of a photoresist or other suitable masking material) may be formed over the final dielectric layer 118, with openings that define the x-y cross-section of the channels (shown here as a circle). One or more etch techniques may be performed to remove the portion of the underlying layers aligned with the opening in the mask to form the transistor body opening. Any type of suitable etching techniques may be used, including but not limited to dry etching, wet etching, or plasma etching techniques. The mask may be removed once the channel openings are defined or may be retained to protect the underlying surface or to remain as part of the final structure.

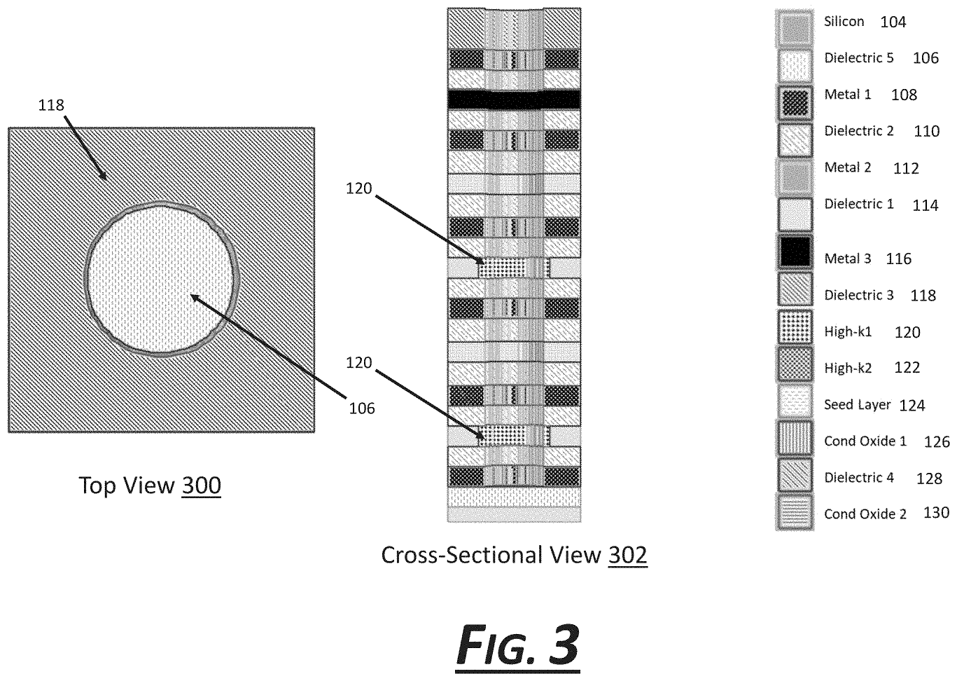

FIG. 3 illustrates a top view 300 and a cross-sectional view 302 of a device at the next stage in the process flow. Once the channel opening(s) are defined, one or more of the gate layers 112 may be etched slightly in the x-y direction to recess the gate from the channel opening. The etching process may be a selective etching process that etches the gate layers 112 to create recessed regions of a predetermined volume, by etching the gate layers 112 (the gate metal) by a predetermined amount. A gate dielectric, such as a high-k dielectric 120 (shown as “High-k1” in the legend), may be selectively formed on the gate layer 112. The high-k dielectric 120 may be grown or deposited such that a predetermined amount of high-K dielectric 120 fills the recessed region of the gate layers 112. Additionally or alternatively, the high-K dielectric 120 may be formed on recessed or non-recessed gate layer 112 so as to extend into the channel opening. The high-k dielectric 120 material may be selected to have desired attributes or properties, such as a desired dielectric constant. Likewise, the high-k dielectric 120 may be grown or deposited to create a predetermined separation distance between the gate layer 112 and the central channel of the transistor structure.

The high-k dielectric 120 and the high-k dielectric 122 (shown as “High-k2” in the legend) may be any type of material that has a relatively large dielectric constant. As one example, a silicon oxide (SiO₂) gate dielectric may be selectively formed on the gate layer. Additionally or alternatively, other gate dielectric materials may be utilized such as silicon oxynitride (SiOₓN_{y}), silicon nitride (Si₃N₄), alumina (Al₂O₃), lanthanum oxide (La₂O₃), zirconium oxide (ZrO₂), hafnium oxide (HfO₂), hafnium zirconium oxide (HfZrO), tantalum oxide (Ta₂O₅), hafnium silicon oxide (HfSiO₄), zirconium silicon oxide (ZrSiO₄), titanium oxide (TiO₂), strontium titanium oxide (SrTiO₃), hafnium silicon oxynitride (HfSiOₓN_{y}), zirconium silicon oxynitride (ZrSiOₓN_{y}), hafnium oxynitride (HfOₓN_{y}), zirconium oxynitride (ZrOₓN_{y}), other suitable materials and combinations thereof. The resulting gate dielectric may be formed (or formed and then etched) to be slightly recessed, flush or slightly protruding relative to the channel opening depending on the desired device characteristics and process parameters.

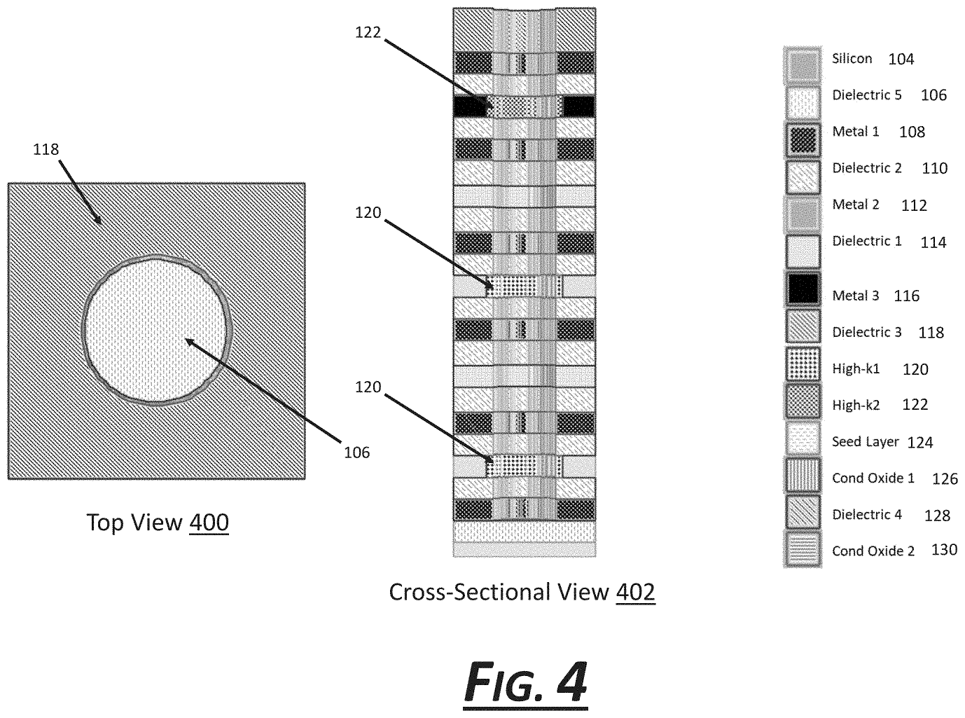

If multiple devices, such as N-type and P-type devices, are exposed in the opening, suitable dielectrics and thicknesses may be provided to each gate to achieve the desired characteristics. Deposition control may be achieved using specific materials for each gate layer 112 and selecting the gate dielectric 120 to form selectively on that gate layer. FIG. 4 illustrates a top view 400 and a cross-sectional view 402 of a device at the next stage in the process flow. Similar to the processes described above in connection with FIG. 3, the gate layer 116 may be recessed using an appropriate etching technique. Then, as shown, a second high-k dielectric 122 may be selectively formed on the gate layer 116. A directional etching may be used to clean the second high-k dielectric 122 outside of the groove on the gate layer 116. The second high-k dielectric 122 may be a different material than the first high-k dielectric 120 and may be deposited following an etching process to recess the gate layer 116.

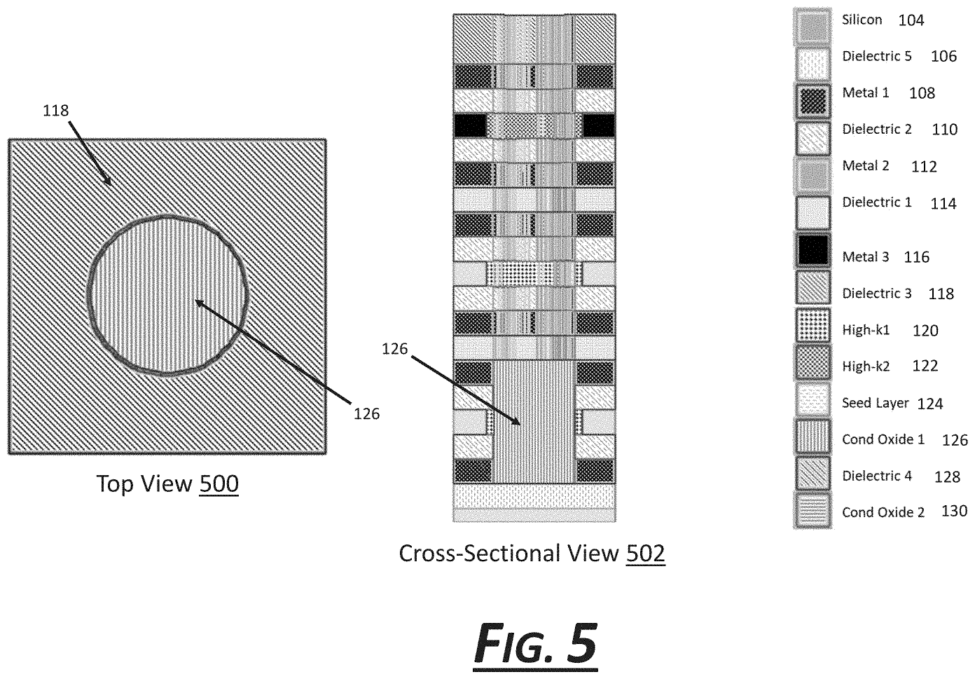

FIG. 5 illustrates a top view 500 and a cross-sectional view 502 of a device at the next stage in the process flow. As shown, the channel opening can be deposit filled with a layer of material, such as a semiconductive-behaving material 126 (e.g., shown as “Cond Oxide 1” in the legend). The deposited material 126 can be any type of conductive oxide material with semiconductive properties. Although the example embodiments may show or describe the deposited material as a semiconductive-behaving material, the deposited material may be a conductive oxide, 2D material, or other similar material and combinations thereof. The semiconductive-behaving material 126 may be formed using certain elements that, when combined with oxygen, form a new material that exhibits semiconductive behavior. For example, the material can be “turned off” with a low off state leakage current or can be “turned on” and become highly conductive when voltage is applied. For example, the semiconductive-behaving material 126 may be an N-type (e.g., N+) conductive oxide, such as In₂O₃, SnO₂, InGaZnO, and ZnO, among others. Alternatively, the semiconductive-behaving material 126 may be a P-type conductive oxide, such as SnO.

Following the deposition of the semiconductive-behaving material 126, the semiconductive-behaving material 126 is then selectively etched to a predetermined height to define a first transistor device. In some implementations, the semiconductive-behaving material 126 may be formed such that the level of the semiconductive-behaving material 126 is at or around the same level as the uppermost S/D layer 108 in the z-direction for the first transistor structure. In a single VFET structure, the semiconductive-behaving material 126 may then be patterned and selectively etched to have an opening, thereby allowing the electrical characteristics of the channel region be defined based on the thickness of the remaining layer. This may form a donut or ring-shaped channel cylinder that is defined on its outermost edge by the channel opening and, if applicable, the gate dielectric layers 120 or 122. If multiple VFET structures are to be stacked, the semiconductive-behaving material 126 of the bottommost VFET structure may not be selectively etched until semiconductive-behaving materials 126 are formed relative to the other VFET structures. By delaying this step, the channel regions may all be defined to their final dimensions simultaneously through the same removal step.

As shown in the cross-sectional view 502, in this implementation the stack of layers may include a single dielectric layer 114 between the S/D layers 108 of adjacent transistor devices. However, it should be understood that any number of dielectric layers may be interposed between adjacent transistor structures, as shown in FIGS. 1-4. Various parameters (e.g., thickness or shape of one or more S/D layers 108, thickness or shape of one or more layers of the gate layers 112 or 116, thickness or shape of one or more layers, thickness or shape of the high-K dielectric 120, thickness or shape of the layers of dielectric 106, the diameter of the central channel, etc.) may be selected prior to the fabrication process to create transistors with desired properties. It should also be appreciated, that other materials may be used for the central channel, such as a 2D material or epitaxial material. In the case of an epitaxial layer, the channel opening etch will reach completely to the substrate 104, which in such an embodiment would be a semiconductor such as silicon. Then, a first layer of material, e.g., SiGe, would be formed followed by the growth of the channel. The SiGe material would subsequently be removed and/or replaced by an isolation material (not shown). Additionally or alternatively, one or more of the channel materials may include an epitaxially grown or polycrystalline deposited semiconductor, such as Si, Ge, or GaAs, among others.

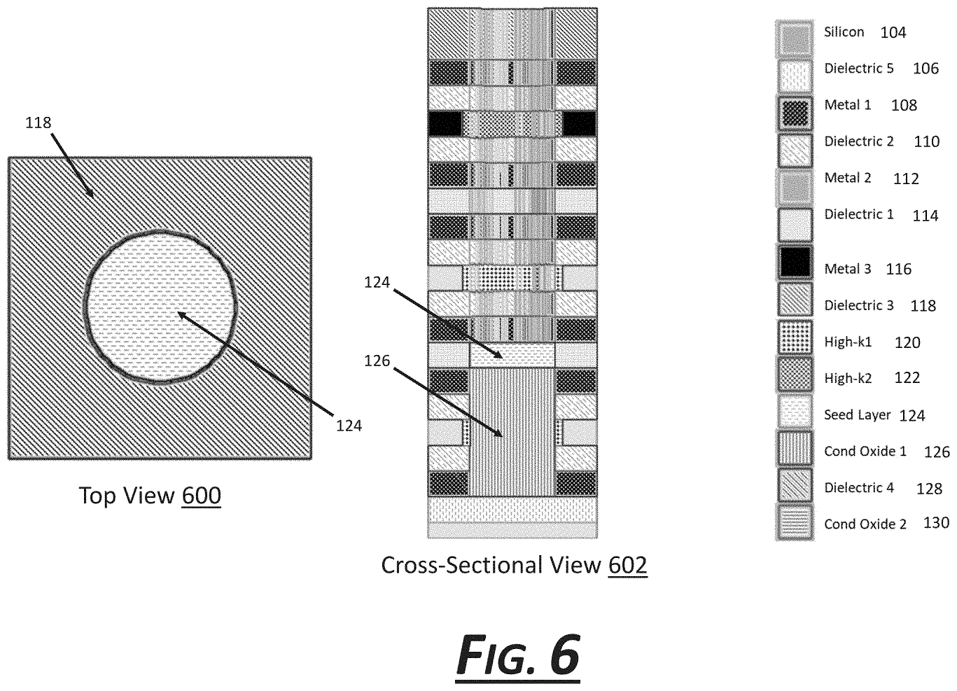

FIG. 6 illustrates a top view 600 and a cross-sectional view 602 of a device at the next stage in the process flow. Once the bottommost transistor is formed by providing the semiconductive-behaving material 126 within the channel opening, a capping layer 124 (shown as the “Seed Layer” in the legend) may be formed on the semiconductive-behaving layer 126. The capping layer 124 may be an insulating, conductive or semiconductive layer, but preferably deposits or grows selectively on the semiconductive-behaving material 126. By having the formation characteristics of the capping layer 124 selected to be preferential to the semiconductive-behaving layer 126, no additional mask step is required. Alternatively, if a non-preferential capping layer 124 is selected, a mask layer may be used to deposit fill the channel opening on top of the semiconductive behaving material 126 with the capping layer 124. In some implementations, the capping layer 124 may be etched by a predetermined amount, such that the thickness of the capping layer 124 maintains the height of the dielectric 114. In some implementations, the selective formation of the capping layer 124 may deposit or form a predetermined amount of the capping layer 124 that matches the height of the dielectric layer 114, eliminating the requirement for an etching step.

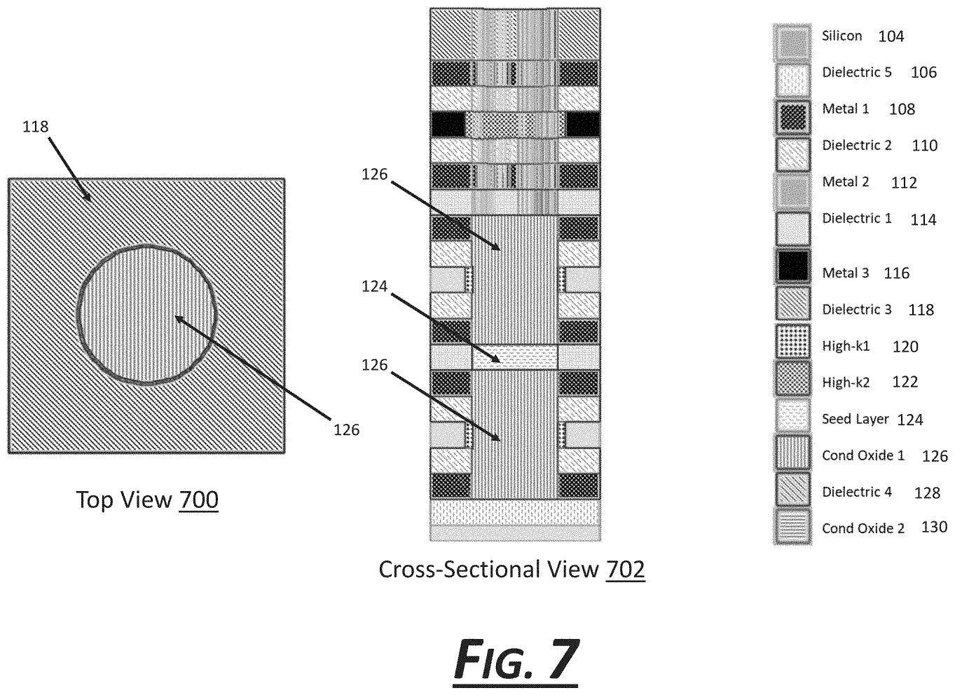

FIG. 7 illustrates a top view 700 and a cross-sectional view 702 of a device at the next stage of the process flow. As shown, in a multiple stacked VFET structure, an additional semiconductive-behaving material 126 is formed on the capping layer 124. The additional semiconductive-behaving material 126 may be the same material as the underlying semiconductive-behaving material 126, or it may be different, though the materials indicated above may be used. For example, utilizing different semiconductive-behaving type materials (e.g., the semiconductive behaving material 130) than what underlies the capping layer provides different types of devices (N-type/P-type or P-type/N-type, for example). Moreover, semiconductive oxides may be used for one channel structure and epitaxial or polycrystalline semiconductors may be used for another channel structure. The structures may be repeated to provide an array of transistors in the x, y, and z directions. The semiconductive behaving material 126 may be deposited on the capping layer 124 using processes similar to those described in connection with FIG. 5. The capping layer 124 may, in some implementations, may serve as a seed layer for the next layer of semiconductive-behaving material 126. In such implementations, the semiconductive-behaving material 126 may be selectively formed and, thus, may not require further masking.

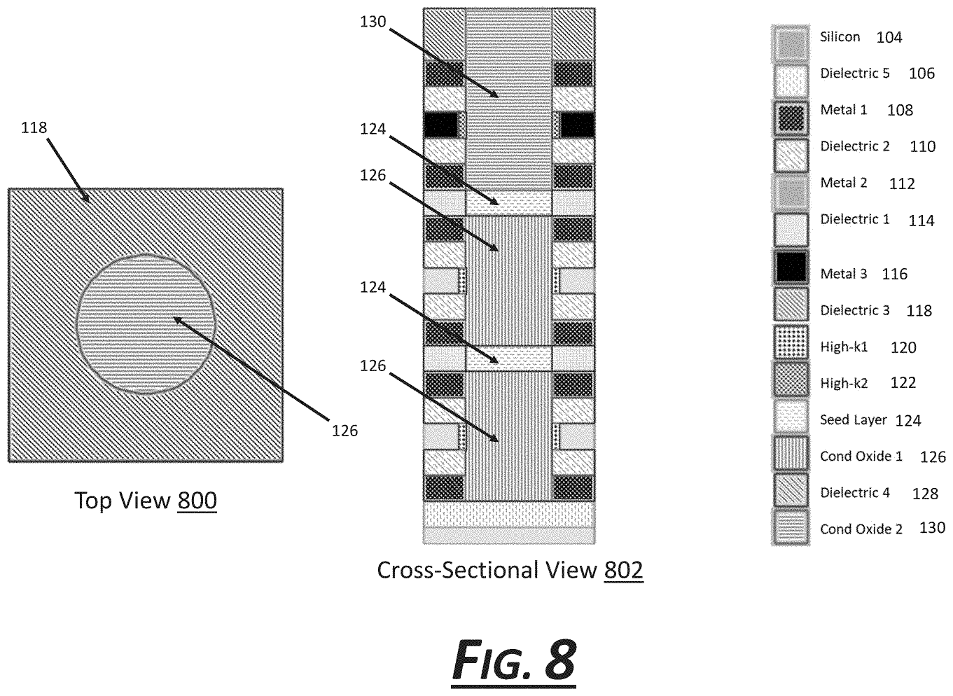

FIG. 8 illustrates a top view 800 and a cross-sectional view 802 of a device at the next stage of the process flow. As shown, the process steps described in connection with FIGS. 6 and 7 are applied to the semiconductive-behaving material 126 to deposit an additional capping layer 124 and subsequently another layer of a different semiconductive-behaving material 130. However, it should be understood that this is shown for example purposes only, and any type of material (e.g., the semiconductive-behaving material 126, etc.) may be used in place of the semiconductive-behaving material 130. This process may be repeated as many times as need to fill or nearly fill the channel opening for another device, shown here as a complementary transistor. For example, these processes may be repeated to create a stack of N transistors in the channel opening.

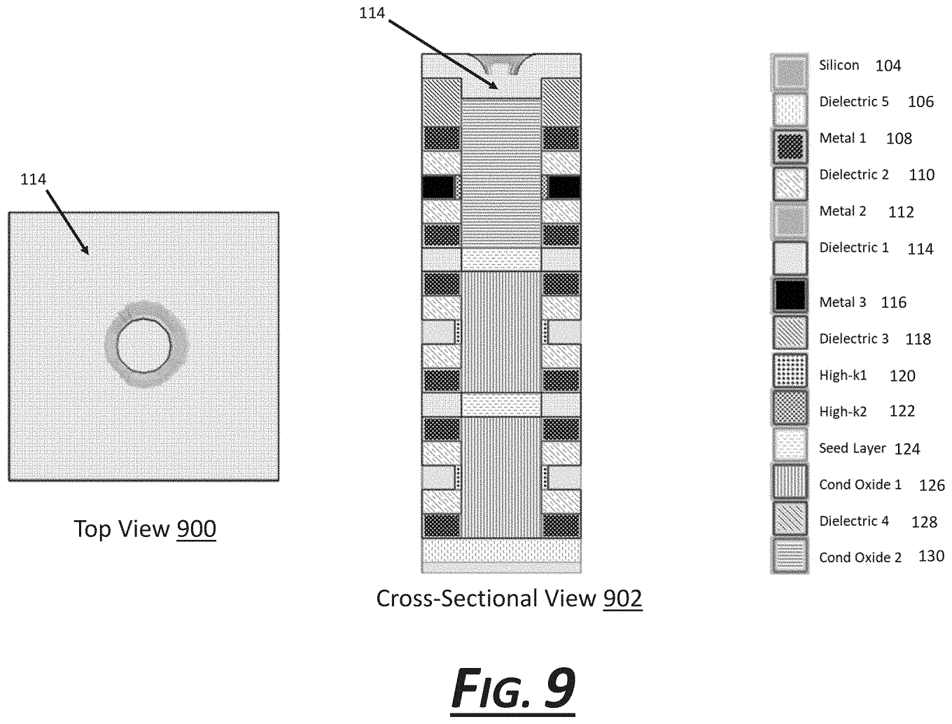

FIG. 9 illustrates a top view 900 and a cross-sectional view 902 of a device at the next stage in the process flow. As shown in the cross-sectional view 902, a patterning layer may be formed to expose a core area of the uppermost semiconductive-behaving material 130. For example, a self-aligned layer of dielectric 114 may be formed (e.g., using an ALD technique) and etched to create a spacer within the channel opening, which can be used to define a core area that is generally in the center of the cylinder-shaped semiconductive-behaving materials 126 and 130.

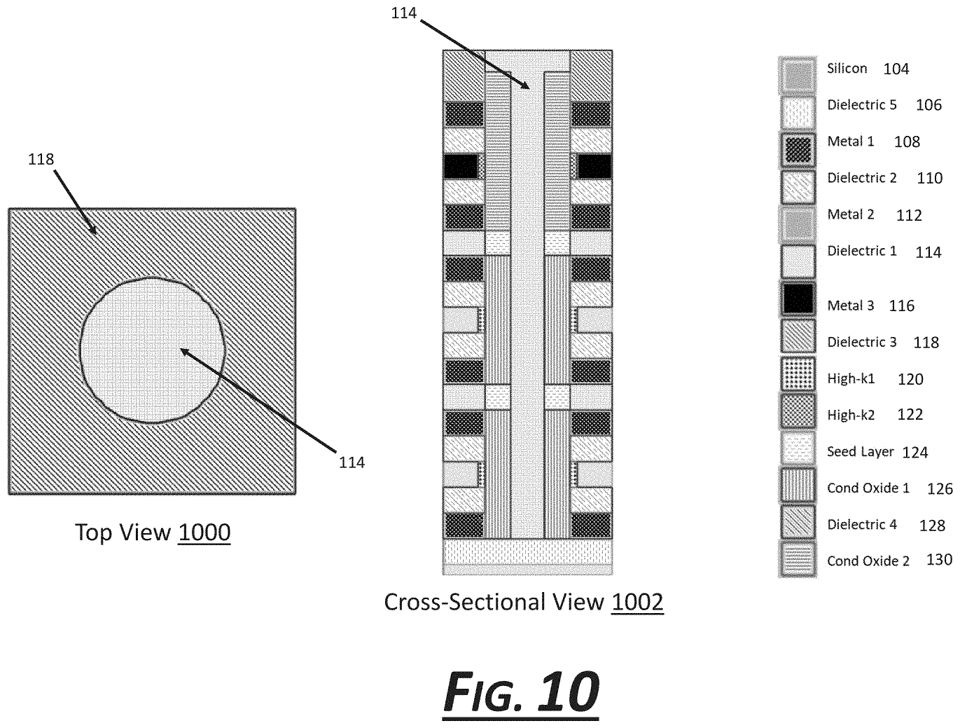

FIG. 10 illustrates a top view 1000 and a cross-sectional view 1002 of a device at the next stage in the process flow. At this stage, a core area may be formed that extends through the device to the dielectric 106 or the substrate 104 using an etching technique. Any type of suitable etchants may then be utilized to define a core region in the semiconductive-behaving materials 126 and 130, as well as the capping layers 124, resulting in controlled channel regions with constant or varying cross-section in the z-direction. The etching process may be any type of etching process, including a dry etching process, a wet etching process, or a plasma etching process, among others. The etch process used to define the core area may be performed until the dielectric 106 layer, or to the substrate 104.

The core area and, if applicable, the area previously occupied by one or more of the capping layers 124 may be filled with a dielectric 114. The dielectric may be deposited or otherwise formed using any suitable deposition technique. By defining a core region of dielectric material 114 in the transistor, the overall volume of the semiconductive-behaving material 126 and 130 are reduced, thereby changing the electronic characteristics of the resulting transistor devices. For example, when the volume of the semiconductive-behaving materials 126 and 130 is reduced, the amount of energy required to turn the transistor to an “on” state is also reduced. The size of the core area etched through the semiconductive-behaving materials can be selected to achieve desired transistor characteristics. Alternatively, these gaps may be left empty to leave an air gap (not shown). If an air gap is desired, the core area may be sealed at the uppermost end of the structure with a capping material (e.g., any of the dielectric materials 106, 110, 114, or 118) to prevent unwanted debris, liquid, moisture, or other material from entering the gap and potentially affecting the devices. A chemical mechanical polishing (CMP) process may then be used to planarize the surface of the stack following the deposition of the dielectric 114.

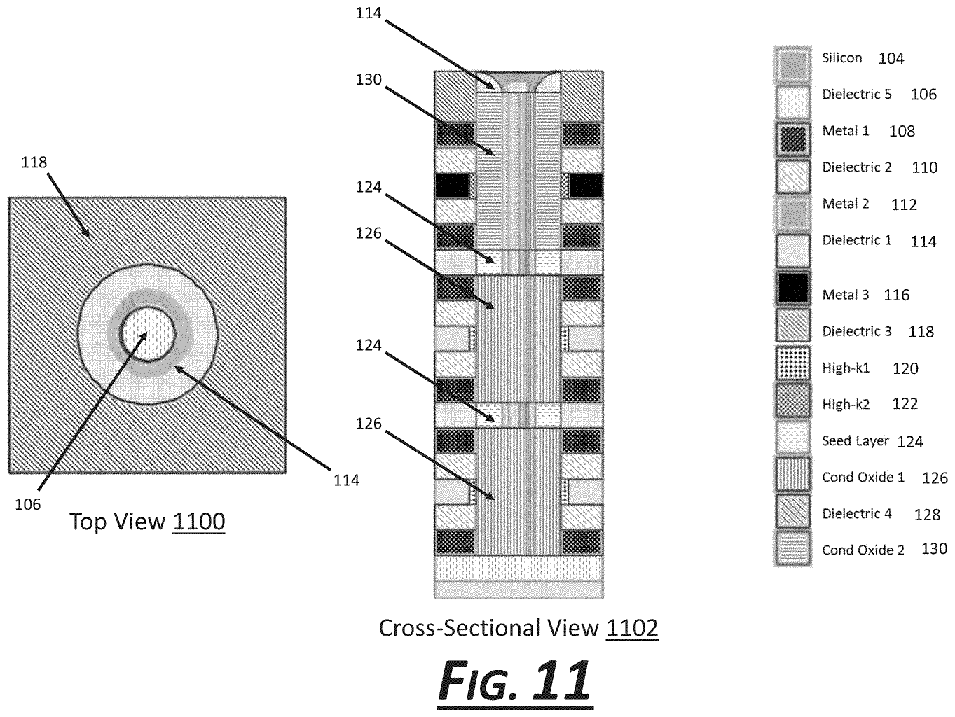

In an alternative process flow, the capping layers 124 may also be removed prior to depositing the dielectric 114 in the gap of the core area. FIG. 11 illustrates a top view 1100 and a cross-sectional view 1102 of a device at an alternative stage in the process flow following the step described in connection with FIG. 9. In this alternative process flow, and as shown in the cross-sectional view 1102, the dielectric 114 positioned at the top of the stack may be directionally etched to create a core are through the semiconductive-behaving material 130, the capping layers 124, and the layers of the semiconductive-behaving material 126. The etching process may stop at the dielectric 106, or in some implementations, at the substrate 104. As shown, a portion of the dielectric 114 may remain on top of the semiconductive-behaving material 130 of the top-most transistor in the stack. The etching process may be similar to the etching process described in connection with FIG. 10.

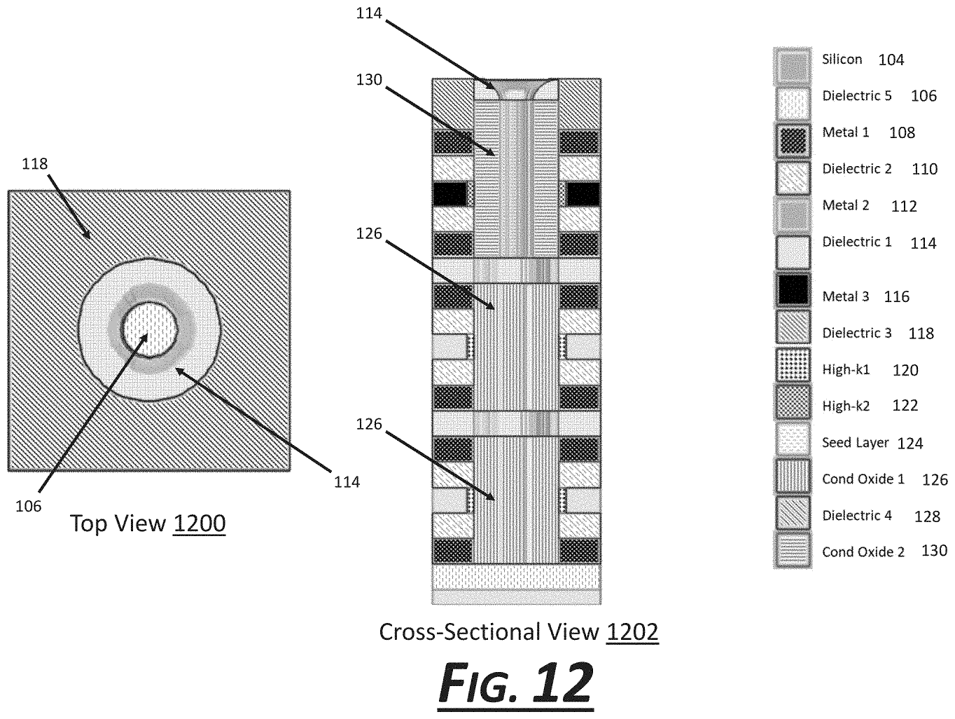

FIG. 12 illustrates a top view 1200 and a cross-sectional view 1202 of a device at the next stage in the process flow following the step described in connection with FIG. 11. At this stage in the process flow, one or more of the capping layers 124 may be removed in the x-y direction. A selective etching process that is selective to the capping layer 124 material may be used to remove the capping layer 124, leaving air gaps that electrically isolate each of the semiconductive-behaving materials 126 and 130 from one another. As shown in the cross-sectional view 1202, the air gaps left after etching the capping layers 124 intersect with the core area.

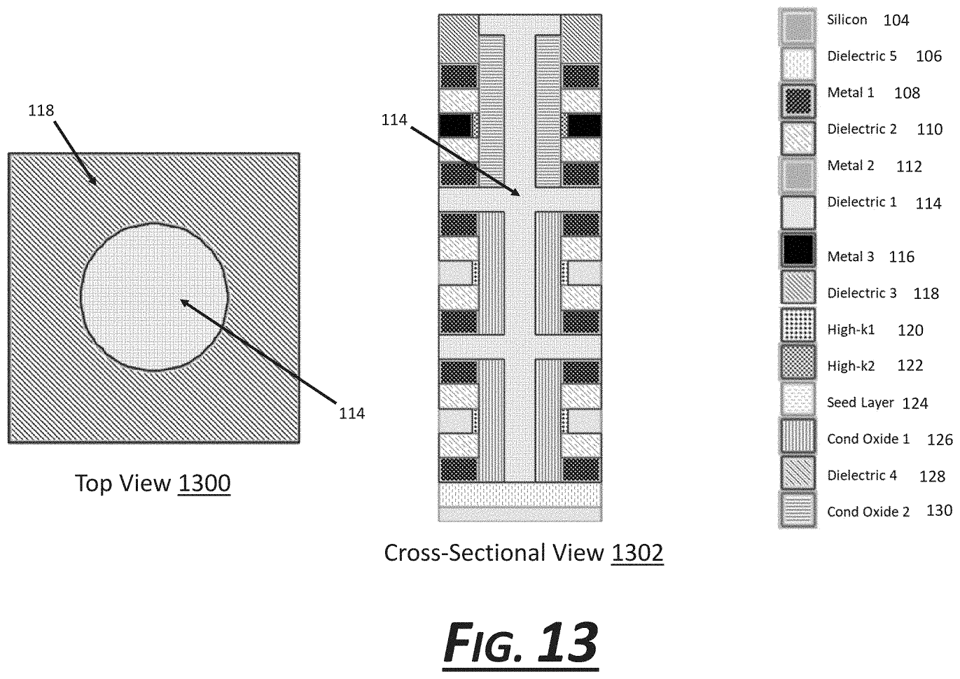

FIG. 13 illustrates a top view 1300 and a cross-sectional view 1302 of a device at the next stage in the process flow following the step described in connection with FIG. 12. At this stage in the process flow, a dielectric material 114 may be deposit filled in the core area and in the air gaps left after etching the capping layers 124. As shown in the cross-sectional view 1302, following the deposition of the dielectric 114, the dielectric 114 both fills the core area previously etched in the process step described in connection with FIG. 11, and also electrically isolates each of the semiconductive-behaving materials 126 and 130 from one another. The dielectric 114 may extend through the transistor devices down to the dielectric 106, or in some implementations, down to the substrate 104 (e.g., if the core area is etched to the substrate). After the deposition of the dielectric 114 fills the core area and the gaps left by etching the capping layers 124, a CMP process may be performed to planarize the surface of the device.

The stack may be further processed (e.g., using patterning and etching techniques at various stages in the process flows described herein) to provide wiring to the gate layers 112 or 116 and the S/D layers 108 (although this wiring is omitted for ease of visualizing various aspects of the figures). The stack may be bonded to other structures to create electronic or electric circuits, such as other logic circuits, memory circuits, sensors, or other devices. The structures may also be connected to circuits and devices underlying the stack in the base substrate 104, if applicable. Connections may be formed between layers by forming vias and/or traces at appropriate stages in the process flow. This enables complex and dense logical circuits to be created in both the z-direction and the x-y directions.

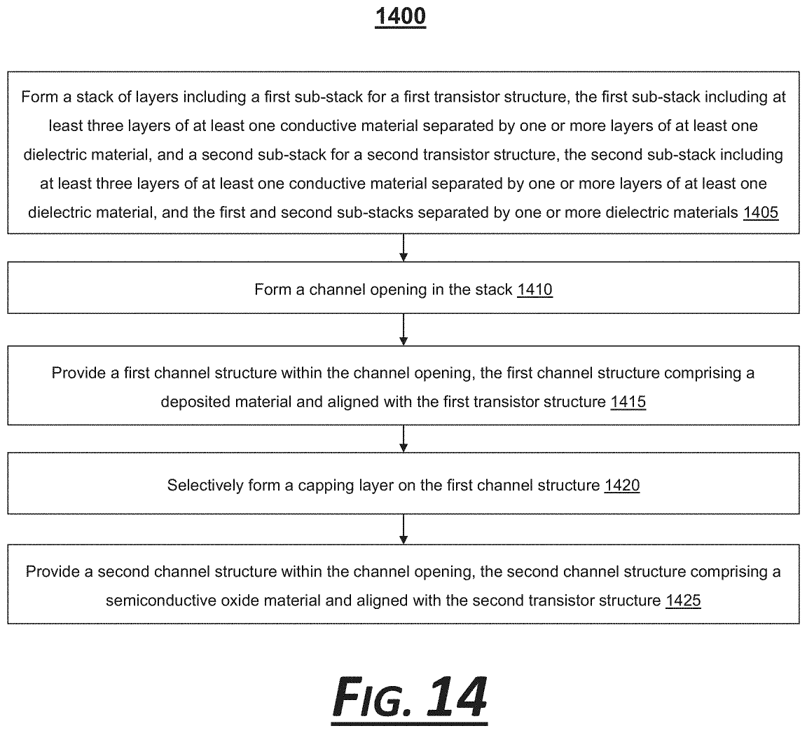

FIG. 14 illustrates a flow diagram of a method 1400 for fabricating 3D semiconductor devices. The method 1400 may include steps 1405-1420. However, other embodiments may include additional or alternative steps, or may omit one or more steps altogether.

At step 1405, the method 1400 includes forming a stack of layers including a first sub-stack for a first transistor structure, and a second sub-stack for a second transistor structure. The first sub-stack can include at least three layers of at least one conductive material (e.g., the S/D layers 108 and at least one gate layer 112 or 116) separated by one or more layers of at least one dielectric material (e.g., the dielectric materials 106, 110, 114, or 118). The second sub-stack can include at least three layers of at least one conductive material (e.g., the S/D layers 108 and at least one gate layer 112 or 116) separated by one or more layers of at least one dielectric material (e.g., the dielectric materials 106, 110, 114, or 118). The first and second sub-stacks can be separated by one or more dielectric materials (e.g., the dielectric materials 114). Additional transistor structures may also be formed by providing additional sub-stacks. The stack of layers may be formed using techniques similar to those described in connection with FIG. 1.

At step 1410, the method 1400 can include forming a channel opening in the stack of layers. The channel opening (sometimes referred to as the “transistor body opening”) may be formed using any type of suitable etching technique, similar to the techniques described in connection with FIG. 2. The transistor body opening may extend through each of the transistor structures in the stack of layers. After defining the channel opening, high-k gate dielectrics (e.g., the gate dielectrics 120 or 122) may be deposited on the gate layers (e.g., the gate layers 112 or 116) in each sub-tack in the stack of layers. To do so, one or more of the gate layers may be recessed, and the high-k gate dielectric materials may be subsequently deposited using techniques similar to those described in connection with FIG. 3. Additional high-k gate dielectrics may also be deposited on gate layers for other sub-stacks using techniques similar to those described in connection with FIG. 4.

At step 1415, the method 1400 can include providing a first channel structure within the channel opening. The first channel structure can include a deposited material (e.g., the deposited material 126 or 130) and can be aligned with the first transistor structure. The first channel structure may be deposited or grown using techniques similar to those described in connection with FIG. 5. To do so, the semiconductive-behaving material may be selectively formed such that the level of the semiconductive-behaving material is at or around the same level as the uppermost layer in the first transistor structure. In some implementations, for example in a single transistor structure, the semiconductive-behaving material may then be patterned and selectively etched to have an opening, thereby allowing the electrical characteristics of the channel region to be defined based on the thickness of the remaining layer. This may form a donut or ring-shaped channel that is defined on its outermost edge by the channel opening and, if applicable, gate dielectric layers in the first sub-stack. If multiple transistor layers are desired, the process flow may proceed to step 1420. In some implementations, following the deposition or formation of the first channel structure, the first channel structure may be directionally etched until a predetermined height is achieved (e.g., flush with, or extending slightly over, the top S/D layer of the first transistor structure).

At step 1420, the method 1400 can include selectively forming a capping layer (e.g., the capping layer 124) on the first channel structure. To do so, techniques similar to those described in connection with FIG. 6 may be performed. In some implementations, the capping layer may be a seed layer on which additional layers of material, such as conductive oxides, may be selectively deposited or grown. The capping layer may be selectively grown on the first channel structure, which is formed at step 1415. The capping layer may be formed to match the thickness of a dielectric that separates the first and second sub-stacks, in a way that does not overlap, or does not substantially overlap, the bottommost S/D layer of the second sub-stack. In some implementations, the capping layer may be selectively etched to achieve a desired height. In some implementations, only a single transistor device layer may be formed, and step 1420 may be omitted from the method 1400.

At step 1425, the method 1400 can include providing a second channel structure within the channel opening. The second channel structure can include a semiconductive oxide material (e.g., the semiconducting-behaving material 126 or 130), and can be aligned with the second transistor structure. The second channel structure be deposited or grown on the capping layer created in step 1420. For example, the second channel structure may be selectively formed by utilizing the capping layer as a seed layer. The semiconductive behaving material may be any type of semiconductive-behaving material and may be an N-type semiconductive oxide or a P-type semiconductive oxide material. The first channel structure and the second channel structure may include same material or may include different materials (e.g., N-type/N-type, P-type/N-type, or N-type/P-type, among other combinations of additional transistor structures in the stack of layers). For example, if the second channel structure is different from the material used in the first channel structure, a CFET device may be formed. In some implementations, only a single transistor device layer may be formed, and steps 1420 and 1425 may be omitted from the method 1400.

After the second channel structure has been formed, additional capping layers and channel structures may be formed to accommodate each transistor structure in the stack of layers. Once a channel structure has been formed for each transistor structure, a final layer of dielectric may be deposited using techniques described in connection with FIG. 9. To do so, a self-aligned layer of may be formed (e.g., using an ALD technique) and etched to create a spacer within the channel opening, which can be used to define a core area that is generally in the center of the first and second channel structures. Once this layer of dielectric is formed, a core region of the first and second channel structures may be removed using etching techniques described in connection with FIG. 10 or 11-13. If the techniques described in connection with FIG. 10 are used, the etched core region may be replaced with a core dielectric (e.g., the dielectric 114), without removing the capping layers. If the techniques described in connection with FIGS. 11-13 are performed, etching techniques may be used to remove both the core region and the capping layers that separate the transistor structures, as described in connection with FIGS. 11 and 12. The etched core regions and the empty regions left by the etched capping layers may then be filled with a core dielectric using techniques described in connection with FIG. 13.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A method comprising:
forming a stack of layers including:
a first sub-stack for a first transistor structure, the first sub-stack including at least three layers of at least one conductive material separated by one or more layers of at least one dielectric material, and
a second sub-stack for a second transistor structure, the second sub-stack including at least three layers of at least one conductive material separated by one or more layers of at least one dielectric material, and
the first and second sub-stacks separated by one or more dielectric materials;
forming a channel opening in the stack of layers;
providing a first channel structure within the channel opening, the first channel structure comprising a semiconductive oxide material and aligned with the first transistor structure;
selectively forming a capping layer on the first channel structure; and
providing a second channel structure within the channel opening, the second channel structure comprising a semiconductive oxide material and aligned with the second transistor structure.

2. The method of claim 1, further comprising removing a core region of the first and second channel structures and replacing the core region with a core dielectric.

3. The method of claim 2, further comprising removing the capping layer and replacing the capping layer with the core dielectric when replacing the core region with the core dielectric.

4. The method of claim 1, wherein the capping layer is a seed layer and the second channel structure is provided by selective formation utilizing the seed layer.

5. The method of claim 1, wherein the first channel structure and the second channel structure are a same material.

6. The method of claim 1, wherein the first channel structure and the second channel structure are a different material.

7. A vertical field effect transistor (VFET) structure comprising:
a stack of layers including:
a first sub-stack for a first transistor structure, the first sub-stack including at least three layers of at least one conductive material separated by one or more layers of at least one dielectric material, and
a second sub-stack for a first transistor structure, the second sub-stack including at least three layers of at least one conductive material separated by one or more layers of at least one dielectric material, and
the first and second sub-stacks separated by one or more dielectric materials;
a channel opening in the stack of layers;
a first channel structure within the channel opening, the first channel structure comprising a semiconductive oxide material and aligned with the first sub-stack;
a second channel structure within the channel opening, the second channel structure comprising a semiconductive oxide material and aligned with the second sub-stack; and
an insulating layer interposed between the first and second channel structures.

8. The VFET structure of claim 7, further comprising a core region including a core dielectric material that extends through each of the first and second channel structures.

9. The VFET structure of claim 8, wherein the insulating layer interposed between the first and second channel structures comprises the core dielectric material.

10. The VFET structure of claim 8, wherein the insulating layer interposed between the first and second channel structures includes a different material than the core dielectric material.

11. The VFET structure of claim 7, wherein the first channel structure and the second channel structure comprise the same material.

12. The VFET structure of claim 7, wherein the first channel structure and the second channel structure comprise a different material.

13. The VFET structure of claim 7, further comprising a capping layer positioned on the second channel structure that insulates the second channel structure from an external environment.

14. A complementary vertical field effect transistor (CFET) structure comprising:
a stack of layers including:
a first sub-stack for a first transistor structure, the first sub-stack including at least three layers of at least one conductive material separated by one or more layers of at least one dielectric material, and
a second sub-stack for a first transistor structure, the second sub-stack including at least three layers of at least one conductive material separated by one or more layers of at least one dielectric material, and
the first and second sub-stacks separated by one or more dielectric materials;
a channel opening in the stack of layers;
a first channel structure within the channel opening, the first channel structure comprising a semiconductive oxide material providing a P- or N- channel type for the first transistor structure;
a second channel structure within the channel opening, the second channel structure comprising a semiconductive oxide material providing a P-type or N- channel type for the second transistor structure, the channel type being different than the first channel structure; and
an insulating layer interposed between the first and second channel structures.

15. The CFET structure of claim 14, further comprising a core region including a core dielectric material that extends through each of the first and second channel structures.

16. The CFET structure of claim 15, wherein the insulating layer interposed between the first and second channel structures comprises the core dielectric material.

17. The CFET structure of claim 15, wherein the insulating layer interposed between the first and second channel structures includes a different material than the core dielectric material.

18. The CFET structure of claim 14, wherein the first channel structure and the second channel structure comprise the same material.

19. The CFET structure of claim 14, wherein the first channel structure and the second channel structure comprise a different material.

20. The CFET structure of claim 14, further comprising a capping layer positioned on the second channel structure that insulates the second channel structure from an external environment.

21. A vertical field effect transistor (VFET) structure comprising:
a stack of layers including a sub-stack for a transistor structure, the sub-stack including at least three layers of at least one conductive material separated by one or more layers of at least one dielectric material
a channel opening in the stack of layers;
a channel structure within the channel opening, the channel structure comprising a semiconductive oxide material and aligned with the sub-stack; and
a core region including a core dielectric material that extends through the channel structure.
